(19) United States
(12) Patent Application Publication
(10) Pub. No.: US 2003/0188685 A1
(43) Pub. Date: Oct. 9, 2003

(54) Laser drilled surfaces for substrate processing chambers

(75) Inventors: Hong Wang, Cupertino, CA (US); Yongxiang He, Sunnyvale, CA (US); Yixing Lin, Saratoga, CA (US); Edwin C. Weldon, Los Gatos, CA (US); Clifford Stow, Santa Clara, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/119,382

(22) Filed: Apr. 8, 2002

(51) Int. Cl. C23C 14/00; C23C 16/00; H01L 21/306; B23K 26/38

(52) U.S. Cl. 118/715; 156/345.34; 204/298.11; 204/298.07; 219/121.71

(57) ABSTRACT

A substrate processing chamber has a component having a surface that is exposed inside the chamber. The exposed surface can have a pattern of recesses that are spaced apart from one another, each recess having an opening, sidewalls, and a bottom wall. The recesses are formed by directing a pulsed laser beam onto a position on a surface of the structure for a time sufficiently long to vaporize a portion of the structure at that position. The component can also be a gas distributor having an enclosure with plurality of laser drilled gas outlets having first and second openings with different diameters to reduce an ingress of a plasma into the enclosure. The laser drilled gas outlets can also have rounded edges.

### BACKGROUND

Embodiments of the present invention relate to substrate processing chambers for processing a substrate.

A substrate processing chamber is used to process a substrate in a process gas to fabricate electronic components, such as for example, integrated circuits and displays. Typically, the chamber comprises an enclosure wall that encloses a process zone into which a gas is introduced and that may be energized to form a plasma. The chamber may be used to deposit material on a substrate by chemical or physical vapor deposition, or etch material from a substrate, or be used for other purposes. The chamber also includes other components, such as for example, a substrate support, gas distributor, and different types of shields. During processing of the substrate, process residues that are generated in the chamber deposit on the exposed surfaces inside the chamber, such as the chamber walls and components.

However, when excessively thick process residues accumulate on the internal chamber surfaces, the residues often flake off, fall upon, and contaminate the substrate being processed. This is especially a problem in sputtering processes when thick residues of sputtered material accumulate on exposed internal chamber surfaces. The thick residues can flake off when a rise in temperature of the surface causes thermal expansion mismatch stresses between the accumulated residues and the underlying structure. It is also a problem in plasma enhanced and thermal CVD processes, because the CVD deposits accumulate on the internal chamber surfaces. Thus, the chamber is typically shut down from time to time, to clean off the accumulated residues from the components. Such chamber downtime is undesirable in the highly competitive electronic industry.

To reduce the cleaning cycles, the internal chamber surfaces are sometimes coated with a coating layer that enhances the adhesion of process residues such as sputtered material. Such a surface coating is described in, for example, commonly assigned U.S. patent application Ser. No.: 09/895,862 by Lin et al. entitled “CHAMBER HAVING COMPONENTS WITH TEXTURED SURFACES AND METHOD OF MANUFACTURE” filed on Jun. 27, 2001, which is incorporated herein by reference in its entirety. While such internal surfaces allow the chamber to be operated for longer periods and increased numbers of process cycles without cleaning, eventually, the accumulated deposits and the underlying coating microcracks or delaminates from the surface. The plasma in the chamber penetrates through such microcracks and damaged areas to erode the exposed surfaces in the chamber. It is desirable to fabricate chamber walls and components having internal surfaces that can tolerate thicker process residues and increased numbers of processing cycles without cleaning.

Another problem arises in the fabrication of components such as gas distributors that are used to supply a gas into the chamber for processing the substrate or as a heat transfer gas below the substrate. Some of these gas distributors have a large number of very fine gas outlet holes having high aspect ratios. For example, showerhead gas distributors facing the substrate may have holes sized less than 0.25 mm (about 0.01 inch) in diameter with aspect ratios of at least 4. The large number of fine holes spreads a flow of process gas more uniformly across the surface of a substrate but are difficult to fabricate, especially in gas distributors made of brittle ceramic materials. Conventional mechanical drilling methods for forming the fine holes often result in non-uniformly sized or unevenly spaced holes, or holes having fractured rough edges, and can also cause microcracking in the region around the hole. Another problem arises when the electrically charged gaseous species of the plasma formed in the chamber enter into the holes of the gas distributor to cause undesirable arcing or glow discharges in the gas distributor. These discharges can erode the holes. Thus, there is a need for a method of fabricating fine holes in such components, and it is also desirable to fabricate holes that reduce undesirable arcing and glow discharges.

### SUMMARY

In one aspect, a component for a substrate processing chamber comprises a structure having a surface that is at least partially exposed to a plasma in the chamber, the exposed surface having a pattern of laser drilled recesses that are spaced apart from one another, each recess having an opening, sidewalls, and a bottom wall.

A kit for a substrate processing chamber can include a plurality of such components. One type of kit includes components that are shields, for example, including include a deposition ring, cover ring, upper gas shield, and lower gas shield.

The component can be fabricated by forming a structure having a surface to be at least partially exposed to the plasma in the chamber; directing a pulsed laser beam onto a position at a surface of the structure to vaporize a portion of the structure to form a recess in the structure, and directing the pulsed laser beam at other positions of the surface of the structure to form a pattern of spaced recesses in the surface of the structure.

In another aspect, a process gas distributor for distributing a process gas into a substrate processing chamber comprises an enclosure, a gas conduit to provide a process gas to the enclosure, and a plurality of laser drilled gas outlets in the enclosure to distribute the process gas into the substrate processing chamber. At least some of the gas outlets may be shaped to have a first opening having a first diameter internal to the enclosure and a second opening having a second diameter internal to the chamber, the second diameter being smaller than the first diameter. Alternatively, or in addition, at least some of the gas outlets may have rounded edges.

### DRAWINGS

These features, aspects, and advantages of the present invention will become better understood with regard to the following description, appended claims, and accompanying drawings which illustrate examples of the invention. However, it is to be understood that each of the features can be used in the invention in general, not merely in the context of the particular drawings, and the invention includes any combination of these features, where:

FIG. 1a is a schematic diagram of a processing chamber according to an embodiment of the present invention;

FIG. 1b is schematic side view of various shields in another processing chamber according to the present invention, showing a deposition ring, cover ring and upper and lower shields, all of which surround a substrate resting on a substrate support in the chamber;

FIG. 2 is a cross-sectional side view of a laser beam drilling recesses in a component of a processing chamber;

FIG. 3a is a cross-sectional side view of rectangular recesses being formed in a component of a processing chamber;

FIG. 3b is a cross-sectional side view of the recesses of FIG. 3a collecting deposition material

FIG. 4a is a cross-sectional side view of angled recesses being formed in a component of a processing chamber;

FIG. 4b is a cross-sectional side view of the recesses of FIG. 4a collecting deposition material;

FIG. 4c is a top view of the recesses of FIG. 4a;

FIG. 5 is a cross-sectional side view of a stepped gas outlet in a gas distributor;

FIG. 6 is a cross-sectional side view of a gas outlet having a trapezoid cross-section in a gas distributor; and

FIG. 7 is a schematic diagram of an embodiment of a controller suitable for operating the chamber shown in FIG. 1a.

### DESCRIPTION

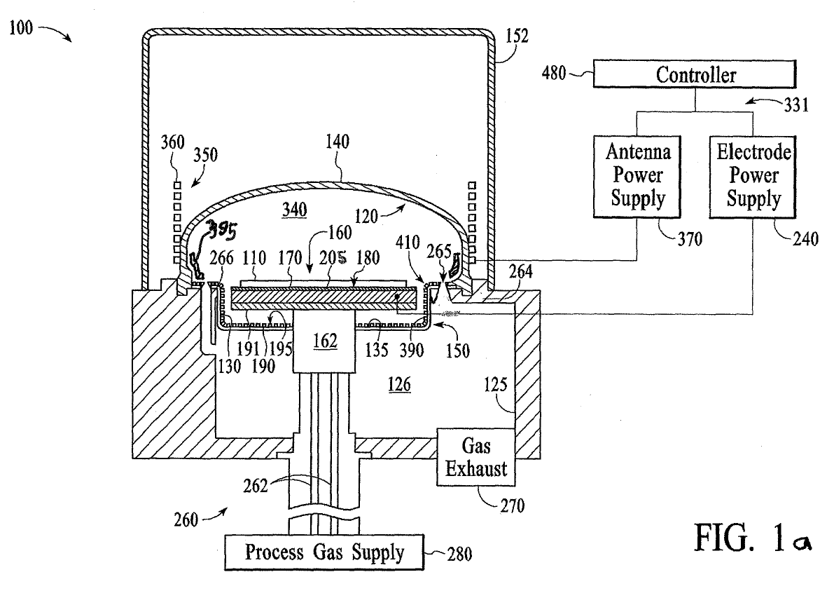

Embodiments of processing chambers 100 according to the present invention, as illustrated in FIGS. 1a and 1b, are used to process a substrate 110 by energizing a gas with heat or in a plasma, to deposit material onto (CVD), sputter material onto (PVD), or remove material from (etch) the substrate 110. For example, a gas may be energized to sputter etch material from a substrate 110 by bombardment of the substrate 110 with ions and neutral particles, for example, to clean and prepare the substrate 110 for subsequent processes. In one version, the chamber 100 may be used to clean a native oxide layer formed on the substrate 110 through oxidation of an underlying metal layer, so that a subsequent metal deposition process may be conducted to deposit a metal layer that makes good electrical contact with the cleaned off underlying metal layer on the substrate 110. The chamber 100 may also be used to sputter material onto a substrate 110 from a target 121. The substrate 110 being processed is typically a semiconducting wafer or a dielectric plate, and may have semiconductor, dielectric, or conductor materials thereon. Typical semiconductor materials include silicon-containing materials such as elemental silicon or silicon compounds, and gallium arsenide. The dielectric materials include silicon dioxide, undoped silicate glass, phosphosilicate glass (PSG), borophosphosilicate glass (BPSG), silicon nitride, and TEOS deposited glass. The conductor materials include aluminum, copper, tungsten silicide, titanium silicide, cobalt silicide, titanium/titanium nitride, and tantalum/tantalum nitride.

A portion or all of the processing chamber 100 may be fabricated from metal or ceramic materials. Metals that may be used to fabricate the processing chamber 100 include aluminum, anodized aluminum, “HAYNES 242,” “Al-6061,” “SS 304,” “SS 316,” and INCONEL, of which anodized aluminum is sometimes preferred. Suitable ceramic materials include quartz or alumina. For example, in one version, the processing chamber 100 comprises a chamber wall 120 around a process zone 340 in the chamber 100 that is fabricated from a ceramic material substantially permeable to RF wavelengths, such as quartz. The chamber wall 120 may comprise a sidewall 130, bottom wall 135, or ceiling 140 of the chamber 100. The ceiling 140 may be dome shaped as shown in FIG. 1a with a multi-radius arcuate shape or may be flat shape as shown in FIG. 1b. A housing 152 is used to prevent electric and magnetic fields external to the processing chamber 100 from interfering with the operation of the chamber 100.

In the embodiment shown in FIG. 1b, the chamber 100 has a number of components 410 that include shields 150 having surfaces 195 exposed to the interior of the chamber 100 to shield components or walls of the chamber 100 from the plasma, receive residue material 250 formed in the plasma, or direct plasma or sputtered species toward or away from the substrate 110. The shields 150 may include, for example, an annular deposition ring 390 around the substrate 110 and a cover ring 391 around the substrate 110. The shields 150 may also include upper and lower gas shields 392, 394, respectively, that are about the substrate 110 and support 160. The shields 150 may also cover a portion of an internal wall of the chamber, such as a liner 395 positioned adjacent to the sidewalls 130 or ceiling 140. The shields 150 may be made of aluminum, titanium, stainless steel and aluminum oxide.

A kit for the chamber 100 is a set of components 410, such as the shields 150, that include, for example, a deposition ring 390, cover ring 391, and upper and lower gas shields 392, 394; but may also be a set of other components as apparent to one of ordinary skill in the art. The kit is generally sold as a set of one or more chamber components 410 that need to be occasionally replaced, repaired or cleaned. For example, a kit of shield components that includes shields 150 such as the deposition ring 390 and cover ring 391 that may be need to be cleaned from time to time after processing of large number of substrates in the chamber. Sometimes as many as 100 for even 500 substrates are processed in the chamber before a kit of the chamber components 410 need to be swapped out. The kit components may also be components 410 that need to be refurbished, for example, by stripping off process residues and a residual coating and applying a new coating on the components 410.

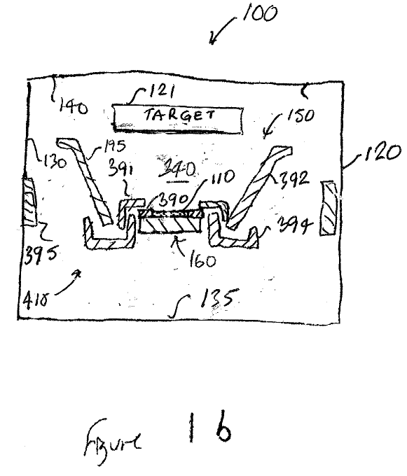

In one aspect of the present invention, a laser beam drill 300 is used to laser drill a pattern of recesses 200 into a surface 195 of a component 410 of the substrate processing chamber 100, as illustrated in FIG. 2. The surface 195 of the component 410 may be exposed to the gas or plasma in the process zone 340 of the chamber 100. Each recess 200 has an opening 230, sidewalls 210, 211, and a bottom wall 220. The component 410 may comprise a metal at the surface 195, such as aluminum, stainless steel, aluminum oxide, or titanium. For example, the component 410 may be one of the aforementioned shields 150, and is especially useful for the components comprising the kit of shields.

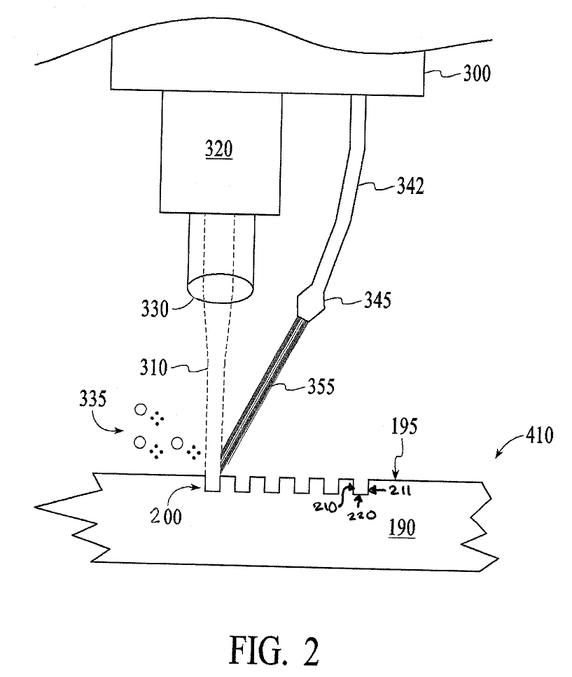

The laser drilled recesses 200 in the surface 195 of the component 410 improve adhesion of the process residues 250 in the plasma, as shown in FIGS. 3a,b. The recesses 200 comprise openings in the structure 190 in which the process residues 250 can collect, and by which the process residues 250 can remain firmly attached to the structure 190. This textured surface 195 provides a high level of adhesion of the process residues 250. By firmly adhering to these process residues 250, the textured surface 195 substantially prevents the flaking off of the process residues 250 from the component 410. The mechanical locking force between the process residues 250 and the structure 190 depends on several factors, including the spacing of the recesses 200, the profiles of the recesses 200, and the local curvature of the structure surface 195.

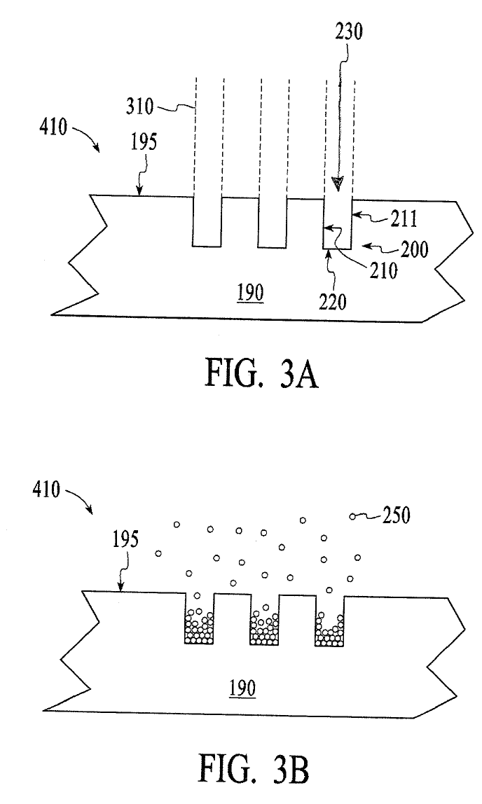

In one embodiment, the sidewalls 210, 211 of the recess 200 are sloped relative to the bottom wall 220, as illustrated in FIGS. 4a and 4b. For example, the sidewalls 210, 211 may be sloped at an angle θ of from about 60 to about 85 degrees from the flat surface 195 of the structure 190. In one embodiment, the sidewalls 210, 211 are sloped such that the size of the recess 200 increases with depth into the recess 200. The sloped sidewall 210, 211 of the recess 200 results in a cross-section having a first size at an opening 230 of the recess 200 into the chamber and a second size at a bottom wall 220 of the recess 200, the second size being larger that the first size. For example, the first size may be at least about 20 microns and the second size may be at least about 30 microns.

The recesses 200 may also have the shape shown in FIG. 4c in which the opening 230 of the recess, as shown by the solid line, is substantially circular in shape, and the bottom portion 220 of the recess 200, as shown by the dotted line, is substantially oval or even elliptical in shape. Such a wedge shaped recess 200 having a tapered cross-section allows the process residues 250 to fill the recesses 200 and remain more strongly attached to the surface 195. The wedge shaped recesses 200 securely hold the residues 250 to the surface 195 because the larger shape of the residues 250 accumulated at the bottom 220 of the recess 200 cannot easily pass through the narrower sized opening 230, thus, better serving to more securely hold the residues 250 to the surface 195. Thus, the sloped-wall recess 200 provides improved retention of the process residues 250. Because the process residues 250 enter the recess 200 and solidify in the recess 200, and because the opening of the recess tapers wider going deeper into the recess 200, the solidified process residues 250 become lodged in the recess 200, as shown in FIG. 4b. The solidified process residues 250 within the recess 200 are strongly bonded to the residues 250 on the surface 195 of the structure 190, and thus, also securely hold the surface residues 250 to the structure 190.

In one version, the exposed surface 195 of the component 410 may be substantially entirely covered by a pattern of the recesses 200 to form a textured surface. The pattern can comprise, for example, a regularly spaced array of the recesses 200, the spacing between the recesses 200 being chosen to optimize the absorption and retention of the process residues 250 by the textured surface 195. For example, if more process residues 250 collect on the surface 195, the recesses 200 can be more densely spaced across the exposed surface 195, thereby allowing the surface to receive and hold a larger amount of residues.

Returning to FIG. 2, the laser beam drill 300 directs a laser beam 310 onto the exposed surface 195 to vaporize the material of the exposed surface 195, effectively creating and deepening a recess 200 in the exposed surface 195. In one embodiment, the laser beam drill 300 comprises a laser beam generator 320 that generates a pulsed laser beam 310 having an intensity that modulates over time. The pulsed laser beam 310 uses a peak pulse power to improve vaporization or liquidisation of the material 335 while minimizing heat loss to provide better control over the shape of the recess 200. The laser energy successively dissociates layers of molecules of the material 335 without excessive heat transfer to the material. The laser beam drill 300 preferably comprises, for example, an excimer laser that generates an ultra-violet laser beam having a wavelength of less than about 360 nanometer, for example, about 355 nanometer. The use of a laser beam with the wavelength longer than 400 nanometers can lead to significant heat production into the workpiece resulting in poor surface morphology and potentially microcracking. A suitable excimer laser is commercially available, for example, from Resonetics, Inc., Nashua, N.H.

The laser beam drill 300 can be controlled by changing one or more of the peak pulse power, the pulse duration, and the pulsing frequency. The pulsed laser beam 310 is operated at a peak power level sufficiently high to remove the desired thickness of material subjected to the laser beam 310. For example, to form a textured surface, the pulsed laser beam 310 is operated at a preselected power level sufficiently high to form a recess 200 having a bottom wall 220 that terminates in the structure 190 without drilling through the entire thickness of the structure 190. However, to form a recess 295, the laser beam power level is set to drill a hole through the thickness of the structure 190. Thus, the laser beam drill 300 generates a laser beam that can form recesses 200 on the surface of the structure 190 or recesses 200 that extend all the way through the structure 190. The laser beam drill 300 is typically a high-power, pulsed UV laser system capable of drilling precise holes of the desired structure, and that can be controlled to set the diameter, depth, tilt angle, taper angle, and rounding level of the edge of the recesses 200.

The laser beam drill 300 provides a pulsed laser beam 310 having a high aspect ratio of up to about 100 for drilling. The laser beam 310 is focused at a point on the structure 190 where a hole is to be formed to transform the material at the point by heating the material to a sufficiently high temperature to liquid and/or vapor phases. The desired hole structure is formed, pulse-by-pulse by removal of liquid and vapor phases from the site. For example, an UV pulsed excimer laser can be operated at a pulse width (time of each pulse) of from about 10 to about 30 nanoseconds, an average power level of from about 10 to about 400 Watts, and a pulsing frequency of from about 100 Hz to about 10,000 Hz. During the 10 to 30 nanosecond pulsed laser operation, the transformation of material from the solid phase to the liquid and vapor phase is sufficiently rapid that there is virtually no time for heat to be transferred into the body of the structure 190. Thus, the high-power UV pulsed laser beam effectively minimizes the size of the area of the structure 190 which is affected by heat during the laser micro-machining process thereby minimizing localized microcracking.

The laser beam drill 300 includes an optical system 330 that can include an auto-focusing mechanism (not shown) that determines the distance between the source of the laser beam 310 and the structure 190, and focuses the laser beam 310 accordingly. For example, the auto-focusing mechanism may reflect a light beam from the structure 190 and detect the reflected light beam to determine the distance to the surface 195 of the structure 190. The detected light beam can be analyzed, for example, by an interferometric method. This auto-focusing mechanism provides improved laser drilling by more properly focusing the laser beam 310, such as when the surface 195 of the structure 190 is not flat.

The laser beam drill 300 may further comprise a gas jet source 342 to direct a gas stream 355 towards the drilling region at the structure 190. The gas stream removes the vaporized material 335 from the region being laser drilled to improve the speed and uniformity of drilling and to protect the focusing lens 330 from the vaporized material. The gas may comprise, for example, an inert gas. The gas jet source 342 comprises a nozzle 345 at some standoff distance from the structure 190 to focus and direct the gas in a stream onto the structure 190.

The structure 190 to be laser drilled is typically mounted on a moveable stage to allow the laser beam drill 300 to be positioned at different points on the surface of the structure to drill recesses 200 therein. For example, a suitable stage can be a 4-5 axis motion system capable of ±1 micron incremental motion in the X, Y, Z directions with a resolution of ±0.5 microns and a maximum velocity of 50 mm/seconds.

Fabricating the component 410 of the substrate processing chamber 100 comprises an initial step of forming the structure 190. The recesses 200 are then laser drilled by directing the pulsed laser beam 310 towards a position on the surface 195 of the structure 190 to vaporize a portion of the structure 190. The pulsed laser beam 310 is directed onto another position on the surface 195 of the structure 190 to vaporize another portion of the structure 190 and form another recess 200 therein. These steps are repeated to create the pattern of recesses 200 in the surface 195 of the structure 190. This process of forming the recesses 200 in the structure 190 is repeated until the exposed surface 195 is substantially entirely covered with the recesses 200. For example, to create the recesses 200 having the sloped sidewalls 210, 211 as shown in FIGS. 4a,b, a pulsed laser beam 310 is directed onto the surface 195 of the structure 190 at incident angles θ₂, θ₃ that are selected to form the sloped sidewalls 210, 211 having angles θ of from about 60 to about 85 degrees with the surface 195 of the structure 190. For example, referring to FIG. 4a, a first laser beam 311a may be directed onto the surface 195 of the structure 190 at an incident angle θ₂ of from about 60 to about 85 degrees to form the sidewall 211 of the structure 190 and then directed onto the surface 195 of the structure 190 at an incident angle θ₃ of from about 95 to about 120 degrees to form the other sloped sidewall 210 of the recess 200, as shown by a second laser beam 311b.

Returning to FIG. 1a, another aspect of the present invention comprises a gas distributor 260 that is useful for providing a process gas into the process zone 340 of the chamber 100 for the processing of the substrate 110. In an etching process, the gas distributor 260 provides an etchant gas into the process zone 340, whereas in a deposition process the gas distributor 260 provides a deposition gas. In a sputter etching process, the etchant gas may comprise an inert gas, such as argon or xenon, which does not chemically interact with the substrate material. The gas distributor 260 is connected to a process gas supply 280 to contain the process gas before it is conveyed inside the chamber 100.

Generally, the gas distributor 260 comprises an enclosure 125 about a cavity 126 to receive and hold the process gas from the gas supply 280 before transferring the gas into the process zone 340. Gas conduits 262 are provided to convey the process gas from the gas supply 280 into the enclosure 125. The enclosure 125 may be intermediate to the process gas supply 280 and the process zone 340, such as the shell surrounding the inner cavity of a gas-releasing showerhead to release the gas above the substrate 110. The enclosure 125 comprises a lower wall, sidewalls, and upper walls that are joined together to define the cavity 126. At least one of the walls of the enclosure 125 has a surface 411 that is exposed to the environment in the process zone 340 of the chamber 100. Each one of the walls may be a separate structure or the walls may be fabricated as a single structure. The enclosure 125 may be made from aluminum, aluminum nitride, aluminum oxide, silicon carbide or quartz.

A plurality of laser drilled gas outlets 265 in the enclosure 125 distribute the process gas into the process zone 340 of the chamber 100. Optionally, the laser drilled gas outlets 265 are spaced apart in a gas trench cover 266 to evenly distribute the flow of the process gas into the process zone 340 of the chamber 100. For example, the enclosure 125 may be on the opposite side of the gas trench cover 266 from the process zone 340 (as shown). The gas outlets 265 are positioned in the gas trench cover 266 to provide uniform dispersion of the process gas in the chamber 100. For example, the gas outlets 265 may be positioned around the periphery of the substrate 110 to introduce the process gas near the substrate 110. The gas distributor 260 may comprise from about 1 to about 20,000 gas outlets 265.

At least some of the gas outlets 265 are tapered to allow the process gas into the process zone 340 while preventing ingress of the process gas back into the enclosure 125. The individual gas outlet 265 comprises a first opening having a first diameter (d1) inside the enclosure 125 and a second opening having a second diameter (d2) outside the enclosure 125, such that the gas outlet 265 is tapered. Typically, the second diameter (d2) is smaller than the first diameter (d1). For example, the second diameter (d2) may be less than about 1 mm (about 0.04 inches), such as about 0.25 mm (about 0.01 inches); and the first diameter (d1) may be less than about 2.5 mm (about 0.10 inches), such as about 2.3 mm (about 0.09 inches).

Forming the gas distributor 260 with the gas outlets 265 comprises the initial step of forming a structure 264 that is at least a portion of the enclosure 125 and has the surface 411 thereon. For example, the structure 264 may be part of the gas trench cover 266. A pulsed laser beam 310 is directed onto the surface 411 of the structure 264 to laser drill the gas outlet 265 therein. The geometry of the cross-sectional area of the focused beam 310 is set during the laser drilling process to either of the first and second diameters (d1, d2). The beam size (width) of the beam 310 can also be adjusted during the laser drilling process to form the tapered gas outlet 265. For example, the beam size may be adjusted by closing or opening an aperture in front of the beam source, or by de-focusing or focusing the beam to change its dimensions.

The second diameter (d2) of the tapered gas outlet 265 is sufficiently smaller than the first diameter (d1) to restrict ingress of a plasma formed in the process zone 340 of the chamber into the enclosure 125. For example, the first diameter (d1) may be at least about 1.3 mm and the second diameter (d2) may be less than about 0.3 mm. The tapered gas outlet 265 is advantageous compared to conventional holes having stepped holes and reduces micro-cracking in the holes during machining and after an anodization process.

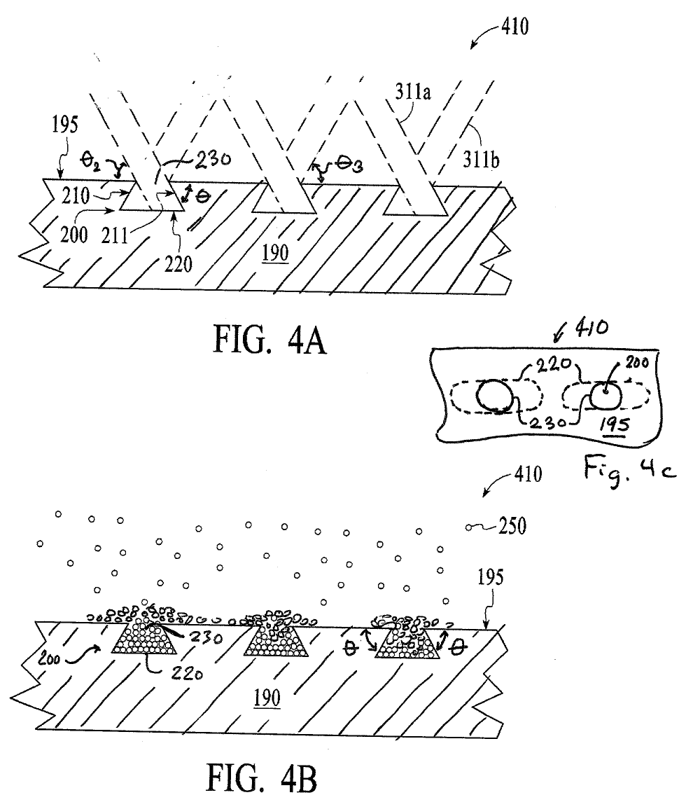

In another embodiment, the gas outlet 265 has a cross-section that is stepped, as illustrated in FIG. 5, with a portion of the length of the outlet 265 having the first diameter (d1) and a portion of the length having the second diameter (d2). This stepped outlet is fabricated by exposing the structure 190 to a first laser beam 310 having a first diameter to reach a first depth, then to a second laser beam 310 having a second diameter to reach a second depth.

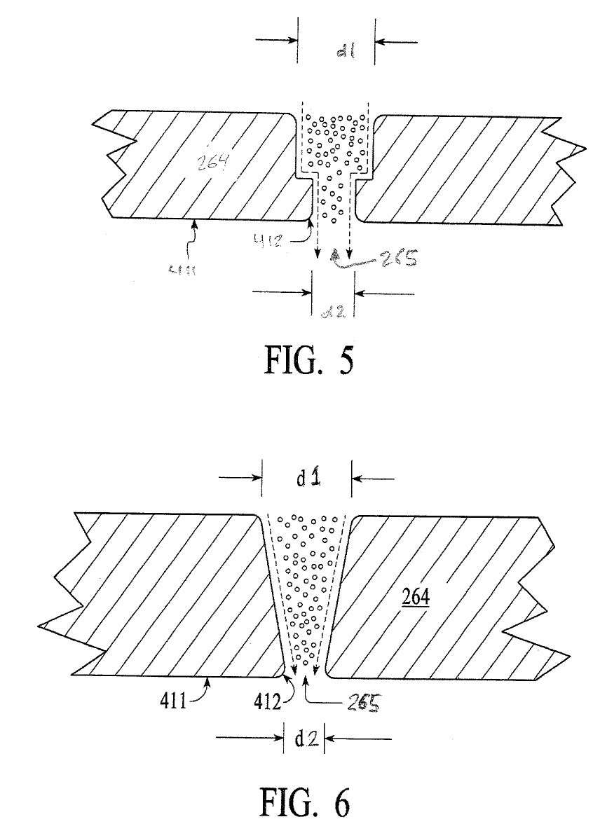

In a preferred embodiment, the gas outlet 265 comprises a cross-section that is substantially continuously tapered, as illustrated in FIG. 6. The cross-section tapers continuously and smoothly to allow the process gas to pass through the gas outlet 265 without a sudden obstruction. This smoothly tapering aperture can be fabricated by exposing the structure 190 to a laser beam 310 having a beam size that continuously decreases in diameter over time while pulsing and remaining positioned at one spot on the structure 190. The continuously tapered cross-section is advantageous because it does not have sharp transitional edges as do stepped cross-sections, which tend to microcrack during fabrication.

The gas outlet 265 may further comprise a rounded edge 412 with a smooth profile that is about the first (d1) or second diameter (d2). The rounded edge 412 allows the process gas to flow smoothly out of the gas outlet 265 without the aerodynamic obstruction caused by a kinked edge. This permits a more efficient flow of the process gas into or out of the gas outlet 265. To achieve the rounded edge 412 about the first (d1) or second diameter (d2), the beam size of the laser beam 310 is adjusted from smaller to slightly larger sizes during the laser drilling process, such as by changing an aperture size in front of the laser beam 310. Advantageously, the laser beam rounded edge is substantially absent microcracks about the edge. Conventional mechanical drilling methods are limited in their ability to achieve smooth rounded edges in the holes and also the mechanical force often causes microcracks around the machined edge, especially in brittle or non-ductile materials such as ceramic materials.

Using a laser beam to drill the pattern of recesses 200 in the chamber component 410, or the gas outlet 265 in the gas distributor 260, allows a higher accuracy and a smaller diameter than mechanical drilling. Furthermore, because there is no contact between a mechanical bit and the structure 190, 264, nor burring of the structure 190, 264, the laser beam drill 300 is longer-lasting and more reliable. Laser drilling is especially advantageous when the recesses 200 or gas outlets 265 described above have multiple diameters because the laser diameter can be readily changed.

Referring back to FIG. 1a, the processing chamber 100 further comprises one or more mass flow controllers (not shown) to control the flow of the process gas into the chamber 100. A gas exhaust 270 is provided to exhaust gas, such as spent process gas, from the chamber 100. The gas exhaust 270 may comprise a pumping channel (not shown) that receives the gas, a throttle valve (not shown) to control the pressure of the process gas in the chamber 100, and one or more exhaust pumps (not shown). The exhaust pump may comprise, for example, a mechanical pump or a turbo pump, such as a 350 I/s Leybold turbo pump. The gas exhaust 270 may also contain a system for abating undesirable gases from the process gas.

The gas composition and pressure in the chamber 100 is typically achieved by evacuating the process zone 340 of the chamber 100 down to at least about 10⁻⁷ Torr before back-filling the chamber 100 with argon to a pressure of a few milliTorr. At these gas pressures, the substrate 110 can be raised upward within the chamber 100. In one embodiment, the processing chamber 100 comprises a knob (not shown) that can be rotated by an operator to adjust the height of the substrate 110 in the processing chamber 100.

Optionally, the processing chamber 100 may also comprises a gas energizer 331 to energize the process gas into a plasma. The gas energizer 331 couples energy to the process gas in the process zone 340 of the processing chamber 100 (as shown), or in a remote zone upstream from the processing chamber 100 (not shown). In one version, the gas energizer 331 comprises an antenna 350 having one or more inductor coils 360. The inductor coils 360 may have a circular symmetry about the center of the processing chamber 100. Typically, the antenna 350 comprises one or more solenoids shaped and positioned to provide a strong inductive flux coupling to the process gas. When the antenna 350 is positioned near the ceiling 140 of the processing chamber 100, the adjacent portion of the ceiling 140 may be made from a dielectric material, such as silicon dioxide, which is transparent to the electromagnetic radiation emitted by the antenna 350, such as RF power. An antenna power supply 370 provides, for example, RF power to the antenna 350 at a frequency of typically about 50 kHz to about 60 MHz, and more typically about 400 kHz; and at a power level of from about 100 to about 5000 Watts. An RF match network (not shown) may also be provided to match the RF power to an impedance of the process gas. In another version, the gas energizer 331 comprises an electrode 205 to create an electric field in the process zone 340 to energize the process gas. In this version, an electrode power supply 240 provides power to the electrode 205, such as at a frequency of from about 50 kHz to about 60 MHz, and more typically about 13.56 MHz. Alternatively or additionally, the gas energizer 331 may comprise a microwave gas activator (not shown).

The processing chamber 100 comprises a substrate support 160 to support the substrate 110 in the processing chamber 100. The support 160 may comprise an electrode 205 covered by a dielectric layer 170 having a substrate receiving surface 180. An electrode power supply 240 provides a DC or AC bias voltage, for example, an RF bias voltage, to the electrode 205 to energize the gas. Below the electrode 205 is a dielectric plate 191, such as a quartz plate, to electrically isolate the electrode 205 from the wall 120 of the chamber 100, some of which may be electrically grounded or floating or which may be otherwise electrically biased relative to the electrode 205. The electrically biased electrode 205 allows etching of the substrate 110 by energizing and accelerating the sputter ions toward the substrate 110. At least a portion the wall 120 that is electrically conducting is preferably grounded, so that a negative voltage may be maintained on the substrate 110 with respect to the grounded or floated chamber wall 120. Optionally, the support 160 may also include an electrostatic chuck (not shown) capable of electrostatically holding the substrate 110 to the support 160, or a DC voltage may be applied to the electrode 205 to generate the electrostatic attractive forces.

The electrode 205 of the substrate support 160 may also comprise one or more channels (not shown) extending therethrough, such as for example, a gas channel (not shown) provided to supply heat transfer gas from a heat transfer gas supply (not shown) to the surface 180. The heat transfer gas, typically helium, promotes heat transfer between the substrate 110 and the support 160. Other channels (not shown) allow lift pins (not shown) to extend through the electrode 205 for loading or unloading of the substrate 110 by a lift mechanism (not shown). The processing chamber 100 may also comprise a support lifting mechanism 162 to raise or lower the support 160 in the processing chamber 100 to improve, or change the nature of, the processing of the substrate 110.

The processing chamber 100 may include additional systems, such as for example, a process monitoring system (not shown) comprising one or more detectors (not shown) that are used to detect or monitor process conditions continuously during an operation of the processing chamber 100, or monitor a process being conducted on the substrate 110. The detectors include, for example, but are not limited to, a radiation sensing device (not shown) such as a photomultiplier or optical detection system; a gas pressure sensing device (not shown) such as a pressure gauge, for example, a manometer; a temperature sensing device (not shown) such as a thermocouple or RTD; ammeters and voltmeters (not shown) to measure the currents and voltages applied to the chamber components 410; or any other device capable of measuring a process condition in the processing chamber 100 and providing an output signal, such as an electrical signal, that varies in relation to the measurable process condition. For example, the process monitoring system can be used to determine the thickness of a layer being processed on the substrate 110.

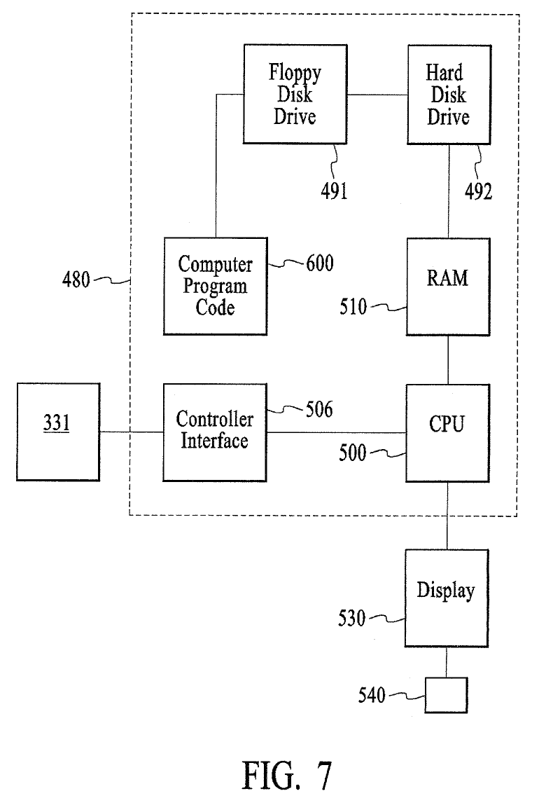

A controller 480 controls operation of the chamber 100 by transmitting and receiving electrical signals to and from the various chamber components and systems. For example, the process conditions measured by the process monitoring system in the processing chamber 100 may be transmitted as electrical signals to a controller 480, which then changes process conditions when the signal reaches a threshold value. In one embodiment, the controller 480 comprises electronic hardware including electrical circuitry comprising integrated circuits that is suitable for operating the processing chamber 100. Generally, the controller 480 is adapted to accept data input, run algorithms, produce useful output signals, and may also be used to detect data signals from the detectors and other chamber components 410, and to monitor or control the process conditions in the processing chamber 100. For example, as illustrated in FIG. 7, the controller 480 may comprise (i) a computer comprising a central processing unit 500 (CPU), which is interconnected to a memory system with peripheral control components, (ii) application specific integrated circuits (ASICs) (not shown) that operate particular components 410 of the processing chamber 100, and (iii) a controller interface 506 along with suitable support circuitry. Typical central CPUs 500 include the PowerPC™, Pentium™, and other such processors. The ASICs are designed and preprogrammed for particular tasks, such as retrieval of data and other information from the processing chamber 100, or operation of particular chamber components 410. The controller interface boards are used in specific signal processing tasks, such as for example, to process a signal from the process monitoring system and provide a data signal to the CPU 500. Typical support circuitry includes, for example, co-processors, clock circuits, cache, power supplies, and other well known components that are in communication with the CPU 500. For example, the CPU 500 often operates in conjunction with a random access memory (RAM) 510, a read-only memory (not shown), a floppy disk drive 491, a hard disk drive 492, and other storage devices well known in the art. The RAM 510 can be used to store computer program code 600 used in the present system during process implementation. The controller interface 506 connects the controller 480 to other chamber components such as the gas energizer 331. The output of the CPU 500 is passed to a display 530 or other communicating device. Input devices 540 allow an operator to input data into the controller 480 to control operations or to alter the software in the controller 480. For example, the interface between an operator and the computer system may be a cathode ray tube (CRT) monitor (not shown) and a light pen (not shown). The light pen detects light emitted by the CRT monitor with a light sensor in the tip of the pen. To select a particular screen or function, the operator touches a designated area of the CRT monitor and pushes a button on the pen. The area touched changes its color or a new menu or screen is displayed to confirm the communication between the light pen and the CRT monitor. Other devices, such as a keyboard, mouse, or pointing communication device can also be used to communicate with the controller 480. In one embodiment, two monitors (not shown) are used, one mounted in a clean room wall for operators and the other behind the wall for service technicians. Both monitors (not shown) simultaneously display the same information, but only one light pen is enabled.

Although the present invention has been described in considerable detail with regard to certain preferred versions thereof, other versions are possible. For example, the present invention could be used with other processing chambers, such as a chemical vapor deposition (CVD) processing chamber or an etching chamber. The processing chamber 100 may also comprise other equivalent configurations as would be apparent to one of ordinary skill in the art. As another example, one or more components 410 of the processing chamber 100 may comprise other laser drilled features. Thus, the appended claims should not be limited to the description of the preferred versions contained herein.

What is claimed is:

1. A component for a substrate processing chamber, the component comprising a structure having a surface that is at least partially exposed in the chamber, the surface having a pattern of laser drilled recesses that are spaced apart from one another, each recess having an opening, sidewalls, and a bottom wall.

2. A component according to claim 1 wherein the surface is substantially entirely covered with the recesses.

3. A component according to claim 1 wherein the recesses comprise sidewalls that are sloped relative to the surface.

4. A component according to claim 3 wherein the sidewalls are sloped at an angle of from about 60 to about 85 degrees relative to the surface.

5. A component according to claim 1 wherein the opening has a first size and the bottom wall has a second size, the first size being smaller that the second size.

6. A component according to claim 1 wherein the structure is a shield.

7. A substrate processing chamber comprising a component according to claim 1, and further comprising:
(a) a substrate support;
(b) a gas distributor to provide a gas into the chamber;
(c) a gas energizer to energize the gas; and
(c) a gas exhaust to exhaust the gas from the chamber.

8. A method of fabricating a component for a substrate processing chamber, the method comprising:
(a) forming a structure having a surface that is at least partially exposed in the chamber;
(b) directing a pulsed laser beam onto a position at a surface of the structure to vaporize a portion of the structure to form a recess in the structure; and
(c) repeating step (b) onto other positions at the surface of the structure to form a pattern of recesses that are spaced apart from one another on the surface of the structure.

9. A method according to claim 8 wherein step (b) comprises directing the pulsed laser beam onto the surface of the structure to form recesses having a sloped sidewall.

10. A method according to claim 8 wherein step (b) comprises directing the pulsed laser beam onto the surface of the structure such that the pulsed laser beam forms an incident angle with the surface of the structure of either (i) from about 60 to about 85 degrees, or (ii) from about 95 to about 120 degrees.

11. A method according to claim 8 wherein, in step (b), the pulsed laser is set at a power level sufficiently high to form recesses having bottom walls that terminate in the structure.

12. A method according to claim 8 wherein step (b) is repeated until the exposed surface is substantially entirely covered with the recesses.

13. A method according to claim 8 wherein step (b) comprises directing the pulsed laser beam onto the surface of the structure to form recesses comprising an opening having a first size and a bottom wall having a second size, the first size being smaller that the second size.

14. A component fabricated according to the method of claim 8, the component having a shape suitable for a shield of the substrate processing chamber.

15. A process gas distributor for distributing a process gas into a substrate processing chamber, the gas distributor comprising:
(a) an enclosure;
(b) a gas conduit to provide a process gas to the enclosure; and
(c) a plurality of laser drilled gas outlets in the enclosure to distribute the process gas into the substrate processing chamber, at least some of the gas outlets comprising a first opening having a first diameter internal to the enclosure and a second opening having a second diameter internal to the substrate processing chamber, the second diameter being smaller that the first diameter.

16. A gas distributor according to claim 15 wherein the gas outlets comprise a cross-section that is substantially continuously tapered.

17. A gas distributor according to claim 15 wherein the first or second openings have rounded edges.

18. A gas distributor according to claim 15 wherein the second diameter is sufficiently smaller than the first diameter to restrict an ingress of a plasma formed in the chamber into the enclosure.

19. A gas distributor according to claim 18 wherein the second diameter is less than about 0.3 mm and the first diameter is at least about 1.3 mm.

20. A gas distributor according to claim 15 wherein the enclosure comprises aluminum, aluminum nitride, aluminum oxide, silicon carbide or quartz.

21. A substrate processing chamber comprising the gas distributor of claim 15, and the chamber further comprising:
(1) a substrate support facing the gas distributor;
(2) a gas energizer to energize the gas introduced into the chamber by the gas distributor; and
(3) an exhaust to exhaust gas from the chamber.

22. A method of forming the gas distributor of claim 15, the method comprising the steps of:
(a) forming a structure that forms at least a portion of the enclosure; and
(b) directing a pulsed laser beam onto a surface of the structure to laser drill the gas outlets therethrough.

23. A method according to claim 22 wherein step (b) comprises adjusting the beam size of the pulsed laser beam from the first diameter to the second diameter, or vice versa.

24. A method according to claim 22 wherein step (b) comprises continuously adjusting the beam size of the pulsed laser beam to form a gas outlet having a cross-section that is substantially continuously tapered.

25. A method according to claim 22 wherein step (b) comprises adjusting the beam size of the pulsed laser beam to round the edges of the gas outlet.

26. A process gas distributor for distributing a process gas into a substrate processing chamber, the gas distributor comprising:
(a) an enclosure;
(b) a gas conduit to provide a process gas to the enclosure; and
(c) a plurality of laser drilled gas outlets in the enclosure to distribute the process gas into the substrate processing chamber, at least some of the gas outlets having rounded edges.

27. A gas distributor according to claim 26 wherein the gas outlets comprise a first opening having a first diameter internal to the enclosure and a second opening having a second diameter internal to the substrate processing chamber, the second diameter being smaller that the first diameter.

28. A gas distributor according to claim 26 wherein the gas outlets comprise a cross-section that is substantially continuously tapered.

29. A substrate processing chamber comprising the gas distributor of claim 26, and the chamber further comprising:
(1) a substrate support facing the gas distributor;
(2) a gas energizer to energize the gas introduced into the chamber by the gas distributor; and
(3) an exhaust to exhaust gas from the chamber.

30. A kit for a substrate processing chamber, the kit comprising a plurality of components, each component comprising a structure having a surface that is at least partially exposed in the chamber, the surface having a pattern of laser drilled recesses that are spaced apart from one another, each recess having an opening, sidewalls, and a bottom wall.

31. A kit according to claim 30 wherein the surface is substantially entirely covered with the recesses.

32. A kit according to claim 30 wherein the components are shields.

33. A kit according to claim 30 wherein the components include a deposition ring, cover ring, upper gas shield, and lower gas shield.

34. A kit for a substrate processing chamber, the kit comprising a plurality of components that include a deposition ring, cover ring, upper gas shield, and lower gas shield, each component comprising a structure having a surface that is at least partially exposed in the chamber, the surface being substantially entirely covered with a pattern of laser drilled recesses that are spaced apart from one another, each recess having an opening, sidewalls, and a bottom wall.
